(19) United States
(12) Patent Application Publication
(10) Pub. No.: US 2025/0208499 A1
(43) Pub. Date: Jun. 26, 2025

(54) METHOD, LITHOGRAPHY MASK, USE OF A LITHOGRAPHY MASK, AND PROCESSING ARRANGEMENT

(71) Applicant: Carl Zeiss SMT GmbH, Oberkochen (DE)

(72) Inventors: Daniel Rhinow, Frankfurt (DE); Markus Bauer, Schneckenlohe (DE); Bartholomaeus Szafranek, Ober-Ramstadt (DE); Horst Schneider, Wiesbaden (DE); Laura Ahmels, Darmstadt (DE); Tilmann Heil, Darmstadt (DE); Hubertus Marbach, Grossostheim (DE); Michael Waldow, Butzbach (DE)

(21) Appl. No.: 19/020,427

(22) Filed: Jan. 14, 2025

Related U.S. Application Data
(63) Continuation of application No. PCT/EP2023/070725, filed on Jul. 26, 2023.

(30) Foreign Application Priority Data
Jul. 28, 2022 (DE) 102022118920.1

(51) Int. Cl. G03F 1/72; G03F 1/22; G03F 7/00

(52) U.S. Cl. CPC G03F 1/72; G03F 1/22; G03F 7/70625; G03F 7/70655; G03F 7/706837

(57) ABSTRACT

A method for checking a lithography mask for a repair of the lithography mask, the lithography mask having a plurality of edges between partial regions of the lithography mask and the object of the repair lying in an adjustment of a profile of a selected edge in a repair portion of the selected edge, comprises:
a) capturing an image representation of a repair region of the lithography mask comprising the repair portion of the selected edge,
b) determining the profile of the selected edge in the repair portion on the basis of the captured image representation of the repair region,
b1) determining a reference profile on the basis of a profile of an edge corresponding to the selected edge, the corresponding edge being an edge which should not be repaired or a portion of the selected edge which should not be repaired, the corresponding edge being determined on the basis of the captured image representation of the repair region, and
c) comparing the determined profile of the selected edge with a reference profile.

### CROSS-REFERENCE TO RELATED APPLICATIONS

This application is a continuation of and claims benefit under 35 U.S.C. § 120 from PCT Application No. PCT/EP2023/070725, filed on Jul. 26, 2023, which claims priority from German Application No. 10 2022 118 920.1, filed on Jul. 28, 2022. The entire contents of each of these earlier applications are incorporated herein by reference.

### TECHNICAL FIELD

The present invention relates to a method for checking a lithography mask, a lithography mask produced using the method, the use of such a lithography mask and a processing arrangement for checking and/or processing a lithography mask.

### BACKGROUND

Microlithography is used for the production of microstructured component parts, for example integrated circuits. The microlithography process is carried out using a lithography apparatus, which has an illumination system and a projection system. The image of a mask (reticle) illuminated by use of the illumination system is projected here by use of the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, EUV lithography apparatuses that use light with a wavelength in the range from 0.1 nm to 30 nm, in particular 13.5 nm, are currently under development. Since most materials absorb light of this wavelength, it is necessary in such EUV lithography apparatuses to use reflective optics, which is to say mirrors, instead of—as previously—refractive optics, which is to say lens elements.

The microstructured components are produced, in particular layer-by-layer, on the basis of a semiconductor substrate such as a silicon wafer. By way of example, a photoresist is initially applied for the purpose of producing a respective layer. The photoresist is cured in a structured fashion, with a lithography mask being used to this end. In this case, the structure specified on the lithography mask is imaged with a reduced size onto the substrate with the photoresist. The photoresist cures at locations with a high illumination intensity, but this is not the case at locations with a low illumination intensity. The non-cured regions can be removed from the substrate in a subsequent rinsing step. Hence, the structure of the lithography mask is transferred in the form of the cured photoresist to the substrate. Now, an etching step or deposition step may be implemented, which affects the substrate only in the free regions where no photoresist is present. Subsequently, the cured photoresist can likewise be removed. To produce a microstructured component, a multiplicity of layers as described above frequently need to be produced one above the other on the substrate. In this case, a dedicated lithography mask is typically required for each layer.

A respective lithography mask is used for the production of a typically very large number of individual components, for example several thousand, several ten thousand, several hundred thousand or even several million. If a lithography mask has a defect, which is to say a structure on the lithography mask is not arranged within an envisaged region, then this defect is transferred to the photoresist, and hence to the substrate, during each exposure procedure using the lithography mask. A microstructured component produced using such a lithography mask may be defective. It is therefore immensely important that the lithography masks used are defect-free. In this context, it is worthwhile to put great effort into the checking and repairing of lithography masks.

Known repair processes are based on particle beam-induced etching or deposition processes, for example, which can be carried out purposefully with a high resolution by the particle beam. However, it is a challenge to determine the suitable process settings for the respective repair and to assess the quality of the repaired region following a repair.

DE 10 2019 218 517 A1 discloses a method for checking microlithographic masks, in which an aerial image of at least one portion of the mask is created and captured by a capture device and compared with a reference image, wherein the comparison of captured aerial image and reference image is implemented by a comparison of image information along at least one comparison line in the aerial image and reference image, with the comparison line extending substantially perpendicular to at least one boundary line of a structure element of the mask.

### SUMMARY

Against this background, it is a general aspect of the present invention to provide an improved method for checking a lithography mask.

According to a first aspect, a method is proposed for checking a lithography mask for a repair of the lithography mask. The lithography mask has a plurality of edges between partial regions of the lithography mask, with the object of the repair lying in an adjustment of a profile of a selected edge in a repair portion of the selected edge. The method comprises the steps of:
a) capturing an image representation of a repair region of the lithography mask comprising the repair portion of the selected edge,
b) determining the profile of the selected edge in the repair portion on the basis of the captured image representation of the repair region,
c) comparing the determined profile of the selected edge with a reference profile for the selected edge, and
d) determining whether the determined profile of the selected edge in the repair portion is located within a predetermined tolerance range in relation to the reference profile, for example on the basis of the comparison of the determined profile with the reference profile.

This method is advantageous in that the profile of the edge per se is taken, independently of further edges of the lithography mask, for the purpose of checking the success of an implemented repair, or else for determining a region on the lithography mask to be processed. In the prior art, a completed repair is typically followed by the determination of the width of a structure delimited by the repaired edge up to an opposite edge, and this is compared with a maximum width (known as the “critical dimension”). However, the determination in this known method also includes variations of the opposite edge, which is why the assessment of the repair is inaccurate and possibly even flawed. In particular, the situation may arise where a repaired edge, determined as successfully repaired using the conventional method, is in fact outside of its specification, possibly leading to defects in the component produced using the lithography mask. This situation can be avoided using the invention since, according to the invention, the profile of the edge is compared with a reference profile, which is why the variation of the opposite edge is not included in the assessment.

The proposed method can be used both to determine a repair shape and to assess a profile of a repaired edge.

The lithography mask comprises at least two partial regions which are separated from one another by edges. The partial regions may also be referred to as a structure element. For example, an absorbing mask has a first partial region, which absorbs incoming light, and has a second partial region, which is substantially transparent to incoming light. An absorber layer, in particular, is present on the lithography mask in the first partial region while the lithography mask is uncoated or coated with a transparent layer in the second partial region. The respective edge forms the boundary between the two partial regions. Depending on the lithography mask technology, the said lithography mask may also comprise phase-shifting partial regions and/or reflective partial regions.

What is of primary importance when assessing the quality of a lithography mask is that a profile of a respective edge is located within a predetermined region, and that the respective edge is as “steep” as possible. An edge is considered ever steeper, the closer an edge angle is to 90°. A steep edge leads to a high contrast or an abrupt transition between the respective partial regions. Further quality parameters include a profile of the edge that is as smooth as possible, which is to say that the scattering of the profile of the edge around a mean of the profile is as small as possible.

The repair to which the lithography mask is or has been subjected has the goal of modifying the profile of the selected edge in such a way that the edge corresponds to a predetermined profile. By way of example, the predetermined profile is given by the reference profile. It would be possible to say that the lithography mask prior to the repair has a defect for example, wherein the defect is characterized by the erroneous profile of the selected edge in the repair portion. In particular, an erroneous profile is given whenever the edge extends outside of the tolerance range around the reference profile at points or in portions.

In particular, the selected edge is the edge which has the defect. The edge selection can be implemented in a preceding examination step, for example when the lithography mask is examined for a lack of faults following the production thereof, or implemented within the scope of an already carried out repair process. By way of example, a location of the selected edge, in particular of the repair portion, is specified by coordinates in relation to the lithography mask. Preferably “edge” in the present case refers to either a complete edge or only an edge portion.

The repair portion, the selected edge and/or the regular or corresponding edge(s), described in detail hereinbelow, can be selected in the image representation or in a further image representation of the lithography mask (or any other lithography mask), preferably by an edge finding method. In this case, a profile of the selected, regular and/or corresponding edge can be determined from the image representation or the further image representation by way of a known image evaluation method, for example by applying a Canny operator, a Sobel operator, a Laplace operator, a thresholding operator, a Roberts operator and/or a Prewitt operator. In an alternative, the repair portion can also be selected manually in the image representation or further image representation. In a further alternative, the repair portion can be chosen on the basis of position information from the repair process of the lithography mask or another lithography mask. Likewise, embodiments provide for the selected, regular or corresponding edge, in particular the repair portion of the selected edge, to be selected on the basis of geometric information from the lithography mask, for example by virtue of knowing the defect points at which the lithography mask was subjected to repair (the selected edge is possibly found here) and where there was no repair (the regular and/or corresponding edge is possibly found here).

An image representation of a repair region of the lithography mask is captured in the first step a). The repair region comprises the selected edge, in particular the repair portion of the selected edge. Thus, in the image representation, the repair region preferably labels a region which is larger than the repair portion and in which at least the selected edge is situated. The repair region may moreover comprise further edges and/or edge portions of the lithography mask, in particular such edges and/or edge portions which need not be repaired. In other words, the repair region may have at least one healthy or defect-free edge. In addition to the selected edge with the repair portion, one or more further edges, which extend within their respective tolerance range around their respective reference profile, may be visible accordingly in the image representation. Presently, these edges are also referred to as regular edges.

The profile of the selected edge in the repair portion is determined from the captured image representation in step b). In particular, this step comprises image processing methods, for example a transformation of the image representation (rotation, stretch, rectification, reflection and the like) and/or a pre-processing of the image representation (contrast increase, resolution change, in particular increase, convolution with a predetermined convolution kernel and the like). The image processing methods may be based on conventional algorithms and/or may also be based on artificial intelligence, in particular neural networks.

The respective edge is labelled in the image representation, in particular in the transformed and/or pre-processed image representation, by way of a high contrast relative to other image regions. Accordingly, the edge can be extracted from the image representation by applying known edge detection methods. If a plurality of edges are visible in the image representation, for example additional regular edges in addition to the selected edge, then the repair region or the image region of the image representation in which the selected edge is located can be selected in a selection step. The selection step can be implemented automatically, for example on the basis of specified coordinates of the location of the selected edge, or else manually by an operator.

If the image representation is in the form of a digital image with a pixel matrix, then the determined profile comprises a set of pixels in particular. This means that the profile is determined by the location of the pixels in the set. The profile is preferably specified by a line. By way of example, the line can be determined by calculating a mean, in particular as a running mean on the basis of the pixels.

Optionally, a step b1) is provided, the latter comprising: determining a reference profile on the basis of a profile of an edge corresponding to the selected edge, the corresponding edge being an edge which should not be repaired or a portion of the selected edge which should not be repaired, the corresponding edge being determined on the basis of the captured image representation or a further image representation of the lithography mask or a further lithography mask.

Preferably, a profile of a corresponding edge is used in step b1) in order to determine the reference profile. The corresponding edge is a regular edge, which is to say a healthy or defect-free edge, as described hereinabove. It preferably has a profile 1, which would correspond to the profile 2 of the selected edge if the latter were also healthy or defect-free. In this case, “corresponding” preferably means that profile 1 and profile 2 are identical within what is technically possible or advantageous. As an alternative or in addition, “corresponding” in this case means that profile 1 and profile 2 correspond to such an extent that the checking method according to steps a)-c) is afflicted by an error that is tolerable for the DUV or EUV range. “Identical” and “corresponding” relate to the shape and/or orientation of the respective edge or respective edge portion, but not to their respective position on the lithography apparatus as this position is generally different.

To find a corresponding edge, one or more of the regular edges can be identified and compared with the selected edge, in particular with one or more defect-free portions of same, or with a repair shape comprising the selected edge and a number (≥1) of regular edges. This can be implemented manually or in automated fashion (edge detection or image evaluation; see hereinabove). If a sufficient correspondence is determined, the corresponding edge is used as a basis for the determination of the reference profile in step b1).

The “further image representation of the lithography mask or a further lithography mask” is preferably an image representation of the lithography mask recorded prior to the repair of the lithography mask or selected edge.

Capturing the image representation (or the further image representation of the lithography mask or another lithography mask) is implemented in particular using an imaging method, for example an electron microscope, in particular a scanning electron microscope. The image representation can also be captured as an aerial image of the lithography mask or repair region. To this end, a wafer print or an aerial image measurement system can be used, for example the AIMS or WLCD systems of the applicant. In these aerial image measurement systems, an aerial image of the lithography mask to be examined is created, during which the imaging settings are similar or virtually identical to the imaging settings in the projection exposure apparatus. In particular, the same illumination settings, or at least similar illumination settings, of an illumination system for illuminating the lithography mask and imaging settings of a projection lens, for example in respect of the polarization or the numerical aperture, comparable to those in the projection exposure apparatus in which the mask is intended to be used can be used in order to reproduce, as accurately or as realistically as possible, how the corresponding imaging of the lithography mask is implemented in the projection exposure apparatus.

The determined profile of the selected edge is compared with a reference profile for the selected edge in step c). In particular, the reference profile is a line, preferably a mathematically exactly defined line, which for example is specified by way of a straight-line equation with start and end points. The reference profile can be specified by a geometric figure, which is aligned at one or more points of the image representation. By way of example the geometric figure is a straight or curved line, which may have corners. The geometric figure may also form a closed shape, for example a triangle, a square, a rectangle, a circle, an ellipse, a star and the like. The geometric figure need not necessarily be symmetrical and/or regular.

In an optional fourth step d), there is a determination of whether the determined profile of the selected edge in the repair portion is located within a predetermined tolerance range in relation to the reference profile, for example on the basis of the comparison of the determined profile with the reference profile. In particular, the tolerance range is a predetermined region around the reference profile, within which the selected edge must extend so that a structure produced using the lithography mask is surely arranged with a sufficient exactness so that the structure fulfils the intended function. The tolerance range can be determined on the basis of the reference profile, for example by specifying a maximum tolerance distance in relation to the reference profile.

Following step b1), c), or in step d), it is possible to determine, firstly, whether first or further processing of the selected edge within a repair method is required. Secondly, it is possible to assess the quality of an implemented repair process. Consequently, it is for example also possible to draw conclusions about advantageous or particularly suitable process settings for a respective repair process, with the result that the respective repair method is continuously improved and optimized over time.

According to an embodiment of the method, step c) comprises virtually overlaying the reference profile for the selected edge on the determined profile, the reference profile being aligned at the selected edge and/or at an edge directly adjacent to the selected edge and/or at an edge connected to the selected edge at an angle which differs from 0° and/or at a corner between portions of the selected edge which extend at an angle with respect to one another which differs from 0°.

In particular “virtually overlaying” is understood to mean that the reference profile and the determined profile are plotted on a joint diagram, wherein the reference profile is aligned in relation to the determined profile at one or more reference positions. By way of example, the respective reference positions are positions of the selected edge outside of the repair portion, and/or positions of an edge adjacent to the selected edge and/or positions of an edge connected to the selected edge at an angle which differs from 0°. The correct alignment of the reference profile with respect to the determined profile is important since the tolerance range relates to the reference profile.

By way of example, the reference profile is a straight line. The selected edge has an interruption and/or an offset in the repair portion. The profile of the selected edge is as desired before and after the repair portion. Then, the reference profile can be aligned to the profile of the selected edge before and after the repair portion in particular. To this end, a respective piecewise mean of the profile of the edge can for example be determined before and after the repair portion, and the reference profile is aligned to the respective mean. In the repair portion, the reference profile then continues to extend correspondingly. It could also be said that the selected edge in the repair portion is interpolated by the reference profile.

According to a further embodiment of the method, the latter comprises:
aligning the reference profile at one or more portions of the selected edge outside of the repair portion.

According to a further embodiment of the method, step c) comprises:
determining the reference profile, on the basis of a profile of an edge corresponding to the selected edge, on the basis of the captured image representation of the repair region.

In particular, an edge corresponding to the selected edge is a regular edge which has the same profile as the one the selected edge should have. Lithography masks frequently have periodic or repeating structures, which is why such a corresponding edge can be determined in the captured image representation with a high probability. However, provision can also be made for the corresponding edge to be determined not in the same image representation but in a further image representation of the lithography mask (or of a further lithography mask) which shows a further or different region of the lithography mask.

In this embodiment, the reference profile is determined directly from the image representation, with the profile of the regular edge serving as a basis in this respect. This is advantageous in that, apart from the captured image representation, no further specifications or pieces of information are required to carry out the method.

It should be observed that the corresponding edge, on the basis of which the reference profile is determined, can be a portion of the selected edge and need not necessarily be a different edge.

According to a further embodiment of the method, determining the reference profile comprises:
applying a low-pass filter and/or piecewise linear regression to smooth the reference profile.

Every real edge on the lithography mask has a statistical variation that depends on the production process. This relates both to a variation in a width of the edge (variation of a flank steepness) and to a variation in a position of the edge. These variations are visible depending on the resolution of the image representation, on the basis of which the reference profile is determined, and may therefore have an effect on the reference profile. Hence the reference profile would likewise have an unwanted statistical variation. In particular, the statistical variations of the reference profile would then also be included in the assessment of the determined profile. This can be avoided by virtue of a low-pass filter being applied to the captured image representation prior to the determination of the reference profile (or else to the already determined reference profile) and/or by virtue of approximating the determined reference profile in piecewise fashion by a linear regression.

According to a further embodiment of the method, determining the reference profile comprises:
determining a plurality of respective profiles of a plurality of edges corresponding to the selected edge and
determining the reference profile as a mean of the plurality of profiles.

This is advantageous in that statistical errors, which are also referred to as mask noise, can be reduced by the calculating the mean.

In embodiments, a respective reference profile is determined on the basis of a reference region in the captured image representation. The reference region is a region of the image representation in which a regular edge is present, the profile of which corresponds to the selected edge, especially in the repair portion of the selected edge. If a plurality of candidates for the reference profile are present in the image representation, then it is possible to accordingly determine a plurality of reference regions. By way of example, the reference regions can be determined by autocorrelation of a section of the image representation comprising the repair portion. By way of example, the plurality of reference profiles can then be averaged, in particular by virtue of the arithmetic mean being calculated pixel-by-pixel or else by virtue of a median being calculated pixel-by-pixel. In this case, forming the median may be advantageous over the arithmetic mean.

According to a further embodiment of the method, the determined profile comprises a number of actual positions of the selected edge and the reference profile comprises a number of corresponding target positions, and wherein, in step d), a distance between the respective actual position and the respective target position is determined and the respective determined distance is compared with a predetermined tolerance value.

As already described above, the respective edge may have a certain width, with the width being measured perpendicular to a nominal profile of the edge in particular. In the case of a curved profile, the nominal profile can be determined point-by-point by a tangent, for example. In this case, the respective actual position is determined as a mean point of the width of the edge at the actual position, for example. It could also be said that the determined profile comprises a set of points, with the individual points being the respective actual positions.

The distance between the actual position and the target position can be determined by subtracting one from the other. If the distance is less than the predetermined tolerance value, then the respective actual position is within the tolerance range. If the respective distance of each of the number of actual positions from its respective target position is less than the predetermined tolerance value, then the corresponding edge overall is tolerable and need not be repaired or processed.

According to a further embodiment of the method, the determined profile comprises a plurality of actual positions of the selected edge, which is a distribution of the actual positions, and wherein, following step b), at least one moment of the distribution is determined and steps c) and d) are carried out on the basis of the at least one determined moment.

By way of example, the moment of the distribution is a mean and can moreover comprise a variance or a standard deviation of the mean or the like.

In particular, a quality measure for assessing the quality of a repair process or an edge, for example a distance of the moment from the reference profile, can also be specified on the basis of the moment and its comparison with the reference profile.

The moment is determined piecewise in some embodiments. By way of example, a repair portion is divided into two or more portions and a respective moment is determined for each of these portions. This embodiment is advantageous in particular in the case of relatively large repair portions and/or curved or kinked profiles.

Steps c) and d) being carried out on the basis of the at least one determined moment is understood to mean that, for example, the moment is compared with a reference profile for the selected edge in step c) and a determination is carried out in step d) as to whether the moment in the repair portion is located within a predetermined tolerance range in relation to the reference profile, on the basis of the comparison of the moment with the reference profile.

According to a further embodiment of the method, the latter comprises:
carrying out a repair process for the selected edge in at least one partial region of the repair portion if the profile of the selected edge, in the at least one partial region, is determined in step d) to be located outside of the tolerance range.

According to a further embodiment of the method, the repair process is carried out on the basis of a difference between the determined profile of the selected edge and the reference profile.

In this embodiment, a repair mask, in particular, is determined on the basis of the difference between the determined profile and the reference profile. A repair mask is a mask which masks those regions in the image representation which should be processed in the repair process. In particular, an etching process for removing material or a deposition process for applying material is carried out in the masked regions during the repair process. The repair mask may also be referred to as repair shape.

According to a further embodiment of the method, the repair process comprises a particle beam-induced etching process and/or deposition process.

Structures can be created with a very high accuracy, in particular a high spatial resolution, by use of particle beam-induced processes. Therefore, edges can be processed with a very high accuracy. The processing accuracy is in the atomic range in particular, meaning that a spatial resolution of the process can be in the Angstrom and nanometer range. By way of example, it is possible to create edges with a spacing of 1 nm. This is particularly advantageously possible by use of electron beam-induced processes (EBIP). The respective particle beam-induced process is preferably carried out under the supply of precursor gases. In this case, the precursor gases are supplied to the position on the lithography mask to be processed and the particle beam is radiated onto the position in focused fashion, which excites and/or decomposes the precursor gases, wherein the excited species and/or decomposition products cause a deposition or an etching of the surface of the lithography mask.

In particular, alkyl compounds of main group elements, metals or transition elements can be considered as precursor gases suitable for the deposition or for growing of elevated structures. Examples of this include cyclopentadienyl(trimethyl)platinum (CpPtMe₃ Me═CH₄), methylcyclopentadienyl(trimethyl)platinum (MeCpPtMe₃), tetramethyltin (SnMe₄), trimethylgallium (GaMe₃), ferrocene (Cp₂Fe), bisarylchromium (Ar₂Cr), and/or carbonyl compounds of main group elements, metals or transition elements, such as, e.g., chromium hexacarbonyl (Cr(CO)₆), molybdenum hexacarbonyl (Mo(CO)₆), tungsten hexacarbonyl (W(CO)₆), dicobalt octacarbonyl (Co₂(CO)₈), triruthenium dodecacarbonyl (Ru₃(CO)₁₂), iron pentacarbonyl (Fe(CO)₅), and/or alkoxide compounds of main group elements, metals or transition elements, such as, e.g., tetraethoxysilane (Si(OC₂H₅)₄), tetraisopropoxytitanium (Ti(OC₃H₇)₄), and/or halide compounds of main group elements, metals or transition elements, such as, e.g., tungsten hexafluoride (WF₆), tungsten hexachloride (WCl₆), titanium tetrachloride (TiCl₄), boron trifluoride (BCl₃), silicon tetrachloride (SiCl₄), and/or complexes with main group elements, metals or transition elements, such as, e.g., copper bis(hexafluoroacetylacetonate) (Cu(C₅F₆HO₂)₂), dimethylgold trifluoroacetylacetonate (Me₂Au(C₅F₃H₄O₂)), and/or organic compounds such as carbon monoxide (CO), carbon dioxide (CO₂), aliphatic and/or aromatic hydrocarbons, and more of the same.

By way of example, the precursor gas for an etching reaction may comprise: xenon difluoride (XeF₂), xenon dichloride (XeCl₂), xenon tetrachloride (XeCl₄), steam (H₂O), heavy water (D₂O), oxygen (O₂), ozone (O₃), ammonia (NH₃), nitrosyl chloride (NOCl) and/or one of the following halide compounds: XNO, XONO₂, X₂O, XO₂, X₂O₂, X₂O₄, X₂O₆, where X is a halide. Further etching gases for etching one or more of the deposited test structures are specified in the applicant's US patent application having the Ser. No. 13/103,281, issued as U.S. patent

Further additional gases that can be used when generating the test structure comprise, e.g., oxidizing gases such as hydrogen peroxide (H₂O₂), dinitrogen oxide (N₂O), nitrogen oxide (NO), nitrogen dioxide (NO₂), nitric acid (HNO₃) and further oxygen-containing gases, and/or halides such as chlorine (Cl₂), hydrogen chloride (HCl), hydrogen fluoride (HF), iodine (I₂), hydrogen iodide (HI), bromine (Br₂), hydrogen bromine (HBr), phosphorus trichloride (PCl₃), phosphorus pentachloride (PCl₅), phosphorus trifluoride (PF₃) and further halogen-containing gases, and/or reducing gases, such as hydrogen (H₂), ammonia (NH₃), methane (CH₄) and further hydrogen-containing gases. These additional gases can be used, for example, for etching processes, as buffer gases, as passivating media and the like.

According to a further embodiment of the method, the reference profile for the selected edge is determined on the basis of a mask design for the lithography mask.

By way of example, the mask design is available in the form of a file, from which an exact profile of the respective edge can be extracted. Preferably, the mask design can be used in addition to the “corresponding edge” for the purpose of retrieving the reference profile.

According to a further embodiment of the method, step a) comprises:
capturing an electron microscope image of the lithography mask and/or an aerial image of the lithography mask and/or an atomic force microscope image of the lithography mask.

A two-dimensional image with a resolution that is as high as possible is sufficient to carry out the method; however, a three-dimensional image, obtained for example by an atomic force microscope, is also suitable for carrying out the method. In the three-dimensional image, the assessment of the steepness of a respective edge, in particular, is better than what is achievable using a two-dimensional image; this may be advantageous in certain cases.

According to a second aspect, a lithography mask is proposed, in particular a lithography mask for EUV lithography which is produced using the method according to the first aspect.

Masks for EUV lithography are reflective masks in particular.

According to a third aspect, the use of a lithography mask according to the second aspect in a lithography apparatus is proposed.

In particular, the lithography apparatus is an EUV lithography apparatus.

According to a fourth aspect, a processing arrangement for checking and/or repairing a lithography mask is proposed. The lithography mask has a plurality of edges between partial regions of the lithography mask. The processing arrangement comprises:
a capture unit for capturing an image representation of a repair region of the lithography mask comprising a repair portion of a selected edge,
a determination unit for determining a profile of the selected edge in the repair portion on the basis of the captured image representation of the repair region, and
a processing unit for comparing the determined profile with a reference profile for the selected edge, wherein
the determination unit is further configured, for example on the basis of the comparison of the determined profile and the reference profile, to determine whether the determined profile of the selected edge in the repair portion is located within a predetermined tolerance range in relation to the reference profile.

In particular, this processing arrangement is configured to carry out the method according to the first aspect. The features and embodiments specified in relation to the method according to the first aspect apply accordingly to the proposed processing arrangement, and vice versa.

The lithography mask is more particularly an EUV lithography mask.

By way of example, the capture unit comprises an electron microscope and/or an apparatus for capturing an aerial image of the lithography mask.

The determination unit and the processing unit can be implemented in the form of hardware and/or software. In the case of an implementation in the form of hardware, the respective unit may be designed for example as a computer or as a microprocessor. In the case of an implementation in the form of software, the respective unit may be designed as a computer program product, as a function, as a routine, as an algorithm, as part of a program code or as an executable object.

The processing arrangement preferably comprises an output unit, for example a visual display unit or a communications interface, for outputting the captured image representation, the determined profile, the reference profile, the comparison of reference profile and profile, and/or the tolerance range. Further, the processing arrangement preferably comprises an input unit, by use of which an operator can implement inputs, for example selecting a determined region in the image representation as the repair region, selecting the edge, selecting the repair portion, inputting and/or selecting the reference profile, and more of the like. In principle, the repair portion in the image representation can also be selected automatically. By way of example, this can be implemented by applying an image evaluation method to the image representation, this for example rendering recognizable the point or points of the lithography mask where a repair took place, in order thus to select these points as respective repair portions.

The repair region is preferably selected and/or defined and/or determined by virtue of a relatively large image portion being determined in the image representation, with the repair portion being used as a starting point. A respective size of the repair region can preferably be selected on the basis of an edge profile and/or a patterning of the lithography mask. By way of example, a size of the repair region can orient itself on a size of the repair portion and can be scaled using the latter as a starting point.

According to an embodiment of the processing arrangement, the latter further comprises a processing unit which is configured to carry out a particle beam-induced etching process and/or deposition process. The processing unit comprises:
a particle beam generation unit for radiating a focused particle beam onto a processing position on the lithography mask, and
a gas supply unit for supplying a precursor gas to the processing position, wherein the precursor gas comprises a gas species which is indirectly or directly convertible into a reactive form by the particle beam, wherein the reactive form of the gas species performs the etching process or the deposition process as a result of a chemical reaction with the lithography mask.

Consequently, processing of the lithography mask can be carried out using the processing arrangement if the determined profile of the selected edge is ascertained to be located outside of the tolerance range in portions.

“A” or “an” in the present case should not necessarily be understood to be restrictive to exactly one element. Rather, a plurality of elements, for example two, three or more, can also be provided. Nor should any other numeral used here be understood to the effect that there is a restriction to exactly the stated number of elements. Instead, unless indicated otherwise, numerical deviations upward and downward are possible.

Further possible implementations of the invention also include combinations, not mentioned explicitly, of features or embodiments described above or hereinafter with respect to the exemplary embodiments. In this case, a person skilled in the art will also add individual aspects as improvements or supplementations to the respective basic form of the invention.

### BRIEF DESCRIPTION OF DRAWINGS

Further advantageous configurations and aspects of the invention are the subject of the dependent claims and also of the exemplary embodiments of the invention that are described hereinafter. The invention is explained in detail hereinafter on the basis of preferred embodiments with reference to the appended figures.

FIG. 1 shows a schematic view of an example of a lithography mask;

FIG. 2 shows an example of an image representation of a repair region of a lithography mask;

FIG. 3 shows an exemplary diagram with a profile of a selected edge and a reference profile;

FIGS. 4A-4F show an example for the steps carried out when repairing an edge and checking the repaired edge;

FIG. 5 shows a further example of an image representation of a repair region;

FIG. 6 shows a schematic block diagram of an exemplary embodiment of a method for checking a lithography mask; and

FIG. 7 shows a schematic view of a processing arrangement.

### DETAILED DESCRIPTION

Unless indicated otherwise, elements that are identical or functionally identical have been provided with the same reference signs in the figures. It should also be noted that the illustrations in the figures are not necessarily true to scale.

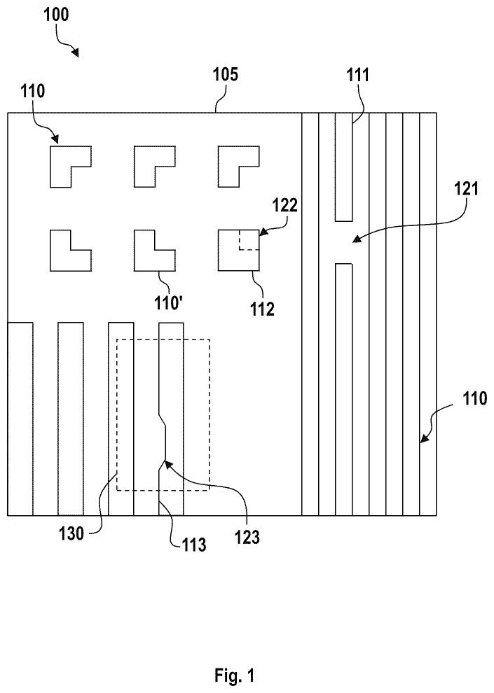

FIG. 1 shows a schematic view of an example of a lithography mask 100. The lithography mask 100 comprises a substrate 105, on which edges 110 are arranged (two of these edges have been provided with a respective reference sign 110 by way of example). A respective edge 110 marks a transition between two partial regions on the surface of the lithography mask 100, with the partial regions having different properties in relation to the incoming radiation. In particular, the substrate 105 of the lithography mask 100 has a first property, for example it is transparent or reflective, and the regions with a different property (in particular a second property) are provided by a sporadic application of a second material, in particular an absorber or phase-shifting material. It could also be said that structures made of the second material are present on the lithography mask 100. By way of example, an EUV lithography mask comprises a reflective substrate surface provided by a Bragg grating, with the structures being produced from an absorber material. Consequently, incident EUV radiation is spatially modulated as the latter is only reflected at points where no structure is arranged. Therefore, the lithography mask 100 has a surface which has been divided into (at least) two regions-those with a structure and those without a structure.

Three edges 111, 112, 113 are plotted individually in FIG. 1. Each of these three edges 111, 112, 113 has a respective repair portion 121, 122, 123 with a defect. By way of example, each of these three edges 111, 112, 113 is a selected edge. The respective repair portion 121, 122, 123 can be selected manually or in automated fashion.

The selected edge 111 has for example an interruption, which should not be present at this position, in the repair portion 121. The selected edge 112 has for example excess material in the repair portion 122. The selected edge 113 has for example a flawed profile of the edge in the repair portion 123. In relation to the selected edge 113, a repair region 130 is also plotted schematically, an image representation thereof being captured within the scope of the method described hereinbelow.

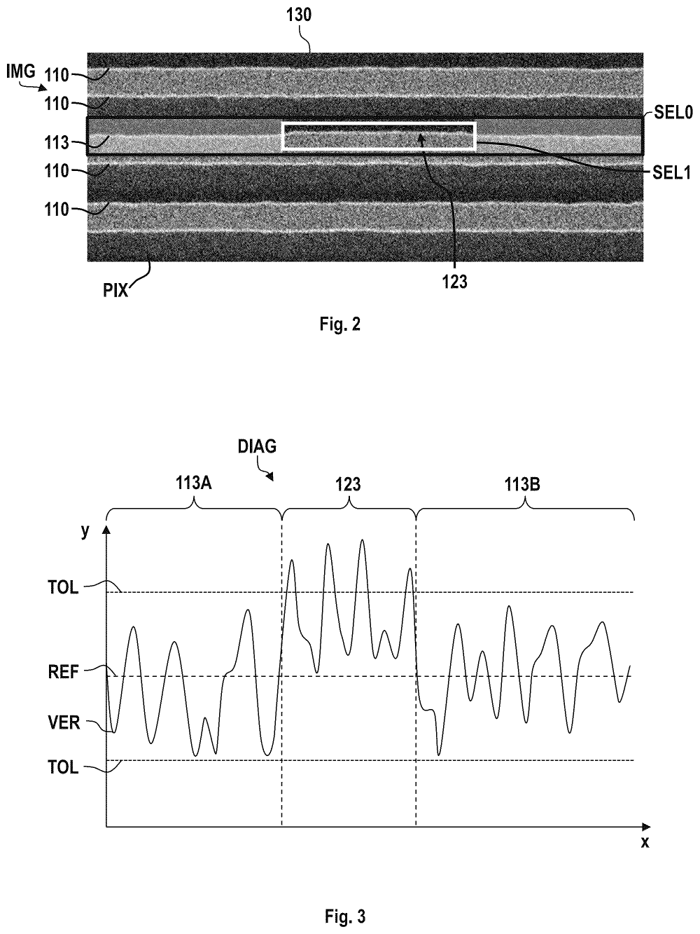

FIG. 2 shows an example of an image representation IMG of a repair region 130 of a lithography mask 100, this for example relating to the repair region 130 depicted in FIG. 1. The image representation IMG was captured using an electron microscope, for example, and has a number of pixels PIX. By way of example, each pixel PIX is defined by its position in the x and y direction (see FIG. 3) and by a greyscale value. In the repair region 130, the lithography mask 100 has line-like structures, with the edges 110 extending substantially parallel to one another. A respective partial region of the lithography mask 100 is located between two respective edges 110, with the lighter regions for example representing structures made of absorber material and the darker regions showing the substrate surface of the lithography mask 100. The selected edge 113 has a repair portion 123, in which the edge extends with an offset; this does not correspond to the specification and may lead to a defect in the produced structure in the case of an exposure using the lithography mask 100.

Two selection regions SEL0, SEL1 are depicted in the image IMG. These selection regions SEL0, SEL1 denote the region of the image representation IMG in which the selected edge 113 is located (selection region SEL0) and in which the repair portion 123 of the selected edge 113 is located (selection region SEL1). Using the selection regions SEL0, SEL1 as a basis, it is possible in particular to determine a profile VER (see FIG. 3) of the selected edge 113 by calculating a mean over the pixels PIX in the image representation IMG assigned to the selected edge 113. The assignment of specific pixels PIX to the edge 113 is implemented on the basis of their greyscale value in particular. In FIG. 3, the mean is calculated in relation to the y position of the assigned pixels PIX, as a function of x.

The selection regions SEL0, SEL1 can be determined in automated fashion, for example on the basis of coordinates of the selected edge 113 and repair portion 123, or else manually. The profile VER of the selected edge 113 can be determined by virtue of applying an edge detection to the selection region SEL0. The selection region SEL1 makes it possible to label the repair portion 123 in the determined profile VER as well. FIG. 3 shows an example of the determined profile VER of the selected edge 113.

FIG. 3 shows an exemplary diagram DIAG with a determined profile VER of a selected edge 113 (see FIG. 1 or 2) and an associated reference profile REF. In particular, this relates to the selected edge 113 in FIG. 2. The diagram DIAG has a horizontal axis x and a vertical axis y. In this example, the x-axis is parallel to the profile of the selected edge 113 and the y-axis is perpendicular thereto. It should be observed that the x-axis and the y-axis have different scalings, which is why deviations in the y-direction are exaggerated.

The deviations of the edge from the specification have their origins in the production of the lithography mask 100 and are more or less pronounced depending on the technology used. This is also referred to as “mask noise.” In particular, the mask noise comprises a statistical deviation of the position of a respective edge from its envisaged target position. It should be noted that defects of a respective edge that need to be repaired are in particular not caused by mask noise but occur on account of other manufacturing errors.

A reference profile REF for the selected edge 113 is depicted in the diagram DIAG. The reference profile REF is a straight line in this example. A tolerance range is also depicted, the latter being delimited by two tolerance lines TOL which are arranged at a predetermined tolerance spacing from the reference profile REF.

The diagram DIAG is subdivided into three portions 113A, 113B, 123 along the x-axis. In this case, the portions 113A, 113B are portions in which the selected edge 113 has an intended profile (also defect-free “portion of the selected edge which need not be repaired” in the present case), more particularly extends within the tolerance range from the reference line REF, and can therefore be used as a reference (consequently a “corresponding edge”). The decision as to whether or not the portions 113A, 113B have an intended profile can be made for example by an operator, by an image or edge detection algorithm and/or on the basis of design data (CAD dataset or the like for manufacturing the lithography mask). The portion 123 is the repair portion 123 of the selected edge 113, within which the edge 113 has an offset (see also FIG. 2) and sporadically extends outside of the tolerance range. The determined profile VER can be considered to be a set of points, with each x-value being assigned a corresponding y-value.

The reference profile REF can be determined in different ways. By way of example, the reference profile REF can be determined on the basis of the determined profile VER of the edge 113 in the portions 113A, 113B. By way of example, the actual profile VER, which is afflicted by statistical variations, can be approximated by a straight line by way of a linear regression. A gradient of 0 may be specified for the straight line since the selected edge 113 extends horizontally. One could also say that a mean of the y-values is determined in portions 113A, 113B. Each y-value can be assigned an individual error in embodiments, with this error being taken into account when carrying out the linear regression or when determining the mean (weighted mean).

An alternative determination method can be based on, for example, the profiles of the further edges 110 (see FIG. 2) in the image representation IMG (see FIG. 2) or in a further image representation (not shown) of the, or any other, lithography mask 100. By way of example, the respective profile is determined for one or more of the further edges 110. Since these edges 110 have the desired or intended profile of the edge 113 in the repair portion 123 (horizontal and straight-lined in this case) and moreover are considered to be regular edges (also referred to as “edge not to be repaired” here), the profile thereof can be used as a reference (and consequently this is a “corresponding edge”). However, since regular edges 110 also exhibit mask noise, it is advantageous in this case to carry out a certain form of averaging. This can be achieved by use of low-pass filtering. Should the image representation IMG have been captured as an aerial image, the image representation is already available in low-pass-filtered form on account of the physics underlying this method. As an alternative or in addition, the profiles of a plurality of regular edges can be determined and these profiles can then be averaged. As an alternative or in addition, a linear regression can be performed.

A further option consists of determining the reference profile manually, for example by an operator. A further option consists of reading the reference profile from a design of the lithography mask 100.

On the basis of the diagram DIAG it is possible to determine that the selected edge 113 is outside of the specification in the repair portion 123, which is why a repair is necessary. To the extent this is an edge that has already been repaired once, it is possible to derive quality features for the performed repair process, for example a smoothness of the repaired edge 113 in the repair portion 123 and a remaining mean offset in relation to the reference profile. Furthermore, optimized process parameters for the repair process can be determined or derived, for example.

It should be observed that the proposed method differs in particular from the determination of structure dimensions (“critical dimension”) for assessing a repair since the determination of structure dimensions always also includes the mask noise of the repaired edge and an opposite edge, and this is avoided by the use of the reference profile REF, determined as proposed, and the tolerance range. Therefore, the proposed method is more exact and less flawed, and allows more accurate conclusions to be drawn about the repair process.

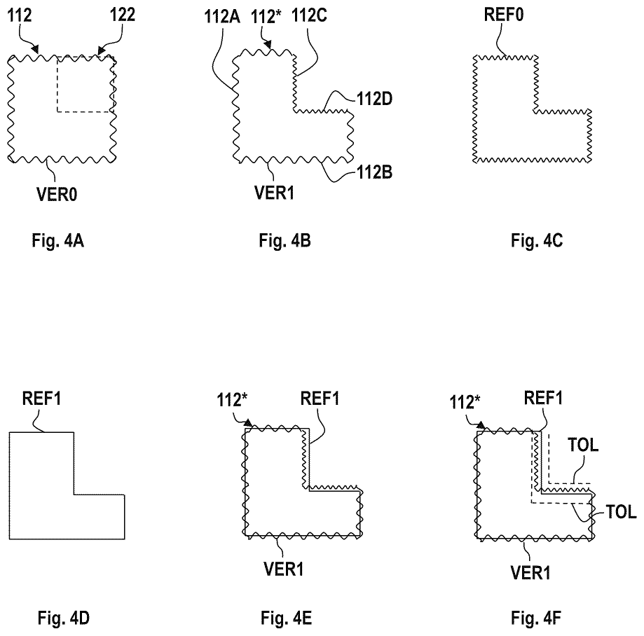

FIGS. 4A-4E show an example for the steps carried out when repairing an edge 112 and checking the repaired edge 112*. By way of example, this is the selected edge 112 of the lithography mask 100 in FIG. 1, which has excess material in a repair portion 122.

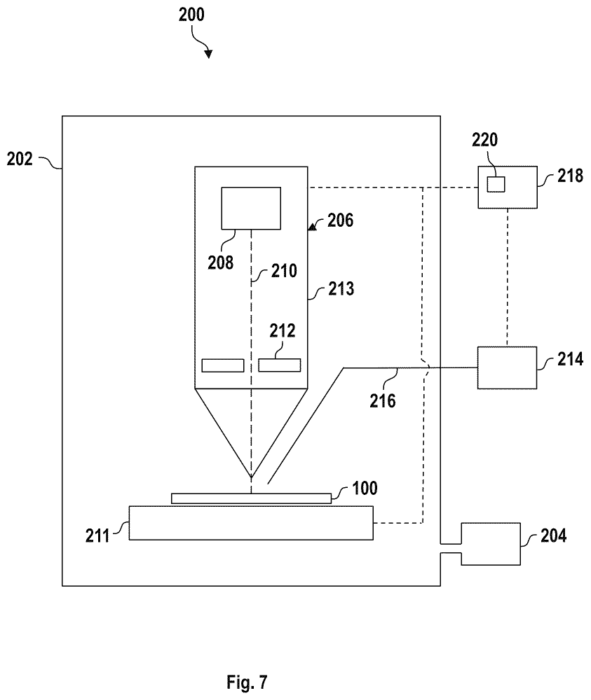

By way of example, FIG. 4A shows the profile VER0 of the selected edge 112 prior to its repair. In this example, the selected edge 112 has a square shape but should have an L shape. The repair portion 122 is depicted in the form of a dashed square. Therefore, the selected edge 112 is repaired, in particular using the processing arrangement 200 described on the basis of FIG. 7.

FIG. 4B shows the profile VER1 of the repaired edge 112*, in which the excess material was removed from the repair portion 122 so that the profile VER1 of the repaired edge 112* has an L shape. The profile VER1 of the repaired edge 112* has two portions 112A, 112B, which are not affected by the repair, and two portions 112C, 112D, which arose as a result of the repair. In this example, the edge portions 112C, 112D have a smaller variation (or a lower mask noise) than the remaining edge portions of the edge 112* since the repair process used for example offers a higher process resolution than the process used to produce the original lithography mask 100. The question arises as to whether the edge portions 112C, 112D of the profile VER1 formed by the repair are located at a correct position, and this is checked on the basis of the reference profile REF1.

By way of example, FIG. 4C shows a first reference profile REF0 which was determined on the basis of regular edges 110 (see FIG. 1) which correspond to the selected edge 112*. This means that, for example, the regular edge 110′, which is arranged next to the selected edge 112 in FIG. 1 and which has the desired L shape, is used as a reference (and consequently is a “corresponding edge”). For example, a profile of the regular edge 110 is determined first and the determined profile is subjected to low-pass filtering, whereby the reference profile REF0 is obtained. The reference profile REF0 is subsequently approximated by (fitted to) a piecewise linear function, for example, with the result that an ideal reference profile REF1, depicted in FIG. 4D, is obtained. In particular, the ideal reference profile REF1 no longer has mask noise. It should be observed that further, more particularly piecewise, low-pass filtering of the reference profile REF0 would be suitable for determining an optimized reference profile, in place of the ideal reference profile REF1 with linear portions. A piecewise smooth profile can be obtained by further low-pass filtering, which may also be applied multiple times in succession.

FIG. 4E shows a virtual overlay of the determined profile VER1 of the repaired edge 112* on the reference profile REF1. In this case, it is important that the reference profile REF1 is correctly aligned with respect to the determined profile VER1. In this example, the reference profile REF1 is aligned in particular with respect to the two portions 112A, 112B of the selected edge 112* which are not influenced by the repair and their corners. The alignment is implemented, in particular, by virtue of a deviation between the portions 112A, 112B and the reference profile REF1 being minimized in these portions. On the basis of this overlay, it is possible to assess whether the repaired edge 112* has a desired profile, in particular whether the latter is within a tolerance range. This is illustrated in FIG. 4F.

Tolerance limit lines TOL are plotted in FIG. 4F on the basis of the reference profile REF1. In FIG. 4F, this is only depicted for the edge portions 112C, 112D which were created during the repair. The tolerance limit lines TOL form a tolerance range. The respective tolerance line TOL has a predetermined distance from the reference profile REF1. Once the tolerance range has been plotted, it is possible to determine whether the repair was successful, which is to say whether the profile VER1 in the edge portions 112C, 112D is located within the tolerance range. This is the case in the illustrated example. Even though the edge portions 112C, 112D visibly and systematically deviate from the reference profile REF1 in this example, the lithography mask 100 with the repaired edge 112* can be used since the edge portions 112C, 112D are within the predetermined tolerance range. Further, quality features for the edge portions 112C, 112D, for example a systematic shift of the respective edge portion 112C, 112D from the reference profile REF1 and the like, can be determined on the basis of FIG. 4F and can be used as a basis for assessing the quality of the repair. Should the repair have failed, conclusions about possible causes can also be drawn on the basis of this evaluation, and hence a repair quality of future repair processes can be improved.

It should be observed that the proposed method differs in particular from the determination and checking of structure dimensions (“critical dimension”), for example a point-wise distance from the edge portion 112A to the edge portion 112C, for assessing the repair since the determination of structure dimensions always also includes the mask noise of the repaired edge and a reference edge, and this is avoided by the use of the reference profile REF, REF0, REF1, determined as proposed, the exact alignment of the reference profile REF, REF0, REF1 and the tolerance range. Therefore, the proposed method is more exact and less flawed, and allows more accurate conclusions to be drawn about the repair process.

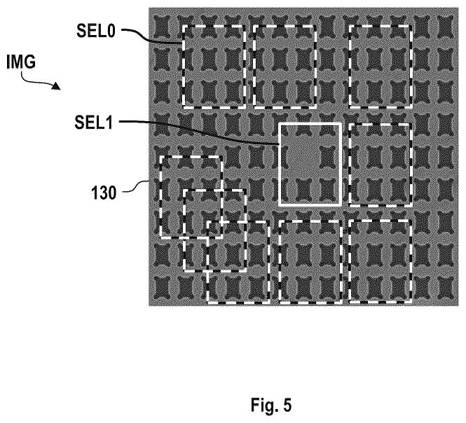

FIG. 5 shows a further example of an image representation IMG of a repair region 130. In this example, the repair region 130 comprises a regular arrangement of structures on the lithography mask 100 (see FIG. 1). However, a defect where the structure is not present is present in the center of the repair region 130. The defect is highlighted by a selection region SEL1. To determine a reference profile REF, REF0, REF1 (see FIG. 3 or 4), it is possible to use in particular regions from the image representation IMG which correspond to the selection region SEL1 and which do not have the defect (and have one or more “corresponding edges”). A plurality of such regions as selection regions SEL0 are depicted using dashed rectangles (for reasons of clarity only one of these selection regions SEL0 has been labelled with a reference sign). By way of example, these selection regions SEL0 can be determined on the basis of the selection region SEL1 by use of an autocorrelation. In this case, for example, the selection region SEL1 is scanned pixel-by-pixel over the image representation IMG and the similarity of the underlying region with the selection region SEL1 is determined. A very high similarity (correlation) is present in the selection regions SEL0, this being the criterion for the selection thereof.

In particular, the selection regions SEL0 can all be used jointly for the determination of the reference profile REF, REF0, REF1, with averaging (as already described above in relation to FIG. 3), for example calculating a mean or a median, being implemented in order to determine a reference from the plurality of selection regions SEL0. This can minimize the influence of the mask noise, which is present in each of the selection regions SEL0. On the basis of the reference obtained thus, it is possible, firstly, to determine a repair shape which may serve as a basis for the repair process to be carried out; secondly, the reference profile REF, REF0, REF1 can be determined from the reference. Advantageously, the reference profile REF, REF0, REF1 determined thus can be aligned on the basis of the selection region SEL1, with the regular edges 110 (see FIG. 1) present in the selection region SEL1 serving as alignment features.

To determine the repair shape, the determined reference is subtracted from the selection region SEL1 (not pictured here), for example. The reference and the selection region SEL1 are in particular each specified as a pixel matrix, with each pixel having a certain value (greyscale value). In this case, identical partial regions of the lithography mask 100 have a respectively similar greyscale value in particular. Therefore, as the reference is subtracted from the selection region SEL1, a difference value close to 0 is obtained for pixels of the same regions. Different regions have a value that differs significantly from 0. By way of example, the repair shape is formed by all pixels whose absolute value of the greyscale value exceeds a predetermined threshold value.

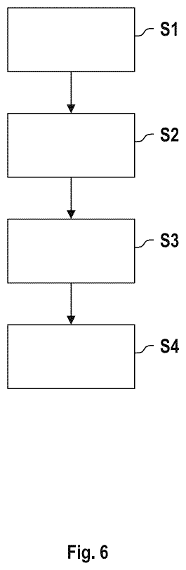

FIG. 6 shows a schematic block diagram of an exemplary embodiment of a method for checking a lithography mask 100 (see FIG. 1) for a repair of the lithography mask 100. The lithography mask 100 has a plurality of edges 110 (see FIG. 1) between partial regions of the lithography mask 100, wherein the object of the repair is to adapt a profile VER (see FIG. 3) of a selected edge 111, 112, 113 (see FIG. 1, 2 or 4A) in a repair portion 121, 122, 123 (see FIG. 1, 2 or 4A) of the selected edge 111, 112, 113. An image representation IMG (see FIG. 2 or 5) of a repair region 130 (see FIG. 1, 2 or 5), comprising the repair portion 121, 122, 123 of the selected edge 111, 112, 113, of the lithography mask 100 is captured in a first step S1. The repair portion 121, 122, 123 can preferably be selected or labelled manually or in automated fashion in the image representation IMG. An operator can select the repair portion 121, 122, 123 in the image representation IMG, for example by way of an input unit. Alternatively, the repair portion 121, 122, 123 can be selected by an image evaluation method, which is applied to the image representation IMG. By way of example, the image representation IMG is captured as an aerial image of the lithography mask 100 or as an electron microscope image. In a second step S2, the profile VER, VER0, VER1 (see FIG. 3, 4A, 4B, 4E or 4F) of the selected edge 111, 112, 113 in the repair portion 121, 122, 123 is determined on the basis of the captured image representation IMG of the repair region 130. By way of example, this is implemented as explained on the basis of FIGS. 2-5 and in particular implemented by determining a reference profile REF, REF0, REF1 on the basis of a profile of an edge 110, 110′, 113A, 113B corresponding to the selected edge 111-113, the corresponding edge 113A, 113B being an edge 110, 110′ which should not be repaired or a portion 113A, 113B of the selected edge 111-113 which should not be repaired, the corresponding edge 110, 110′, 113A, 113B being determined on the basis of the captured image representation IMG of the repair region 130. In a third step S3, the determined profile VER, VER0, VER1 of the selected edge 111, 112, 113 is compared with the reference profile REF, REF0, REF1. In particular, this comparison can be implemented graphically by way of a virtual overlay. In an optional fourth step S4, there is a determination (in an embodiment on the basis of the comparison of the determined profile VER, VER0, VER1 with the reference profile REF, REF0, REF1) as to whether the determined profile VER, VER0, VER1 of the selected edge 111, 112, 113 in the repair portion 121, 122, 123 is located within a predetermined tolerance range in relation to the reference profile REF, REF0, REF1.

Depending on the result of this method, a repair of the selected edge 111, 112, 113 can be prompted, a quality for an implemented repair can be determined and/or conclusions with regard to suitable process parameters for a repair process can be drawn. If a repair of the selected edge 111, 112, 113 is prompted, then the reference profile REF, REF0, REF1 can in particular also be used to determine a suitable repair shape.

The proposed method is preferably carried out using a processing arrangement 200 as explained below on the basis of FIG. 7.

FIG. 7 shows a schematic exemplary embodiment of a processing arrangement 200. The processing arrangement 200 is configured to check and/or repair a lithography mask 100. By way of example, the lithography mask 100 has a form as explained on the basis of FIG. 1 and has a plurality of edges 110 (see FIG. 1) between partial regions of the lithography mask 100. The processing arrangement 200 comprises a capture unit 212 for capturing an image representation IMG (see FIG. 2 or 5) of a repair region 130 (see FIG. 2 or 5), comprising a repair portion 121, 122, 123 (see FIGS. 1-4A) of a selected edge 111, 112, 113 (see FIG. 1, 2 or 4A), of the lithography mask 100. In this example, the capture unit 212 is in the form of an electron microscope. The processing arrangement 200 further comprises a determination unit 218 for determining a profile VER, VER0, VER1 (see FIG. 3, 4A, 4B, 4E or 4F) of the selected edge 111, 112, 113 in the repair portion 121, 122, 123 on the basis of the captured image representation IMG of the repair region 130. In this example, the determination unit 218 forms a control computer for the processing arrangement 200. Furthermore, the processing arrangement 200 comprises a processing unit 220 which is configured to compare the determined profile VER, VER0, VER1 with a reference profile REF, REF0, REF1 (see FIG. 3, 4C or 4D) and which is a constituent part of the determination unit 218 in this example. Preferably, the processing unit 220 is configured to determine the reference profile REF, REF0, REF1 on the basis of a profile of an edge 110, 110′, 113A, 113B corresponding to the selected edge 111-113, the corresponding edge 110, 110′, 113A, 113B being an edge 110, 110′ which should not be repaired or a portion 113A, 113B of the selected edge 111-113 which should not be repaired, the corresponding edge 110, 110′, 113A, 113B being determined on the basis of the captured image representation IMG of the repair region 130. The determination unit 218 is further configured to determine (in an embodiment on the basis of the comparison of the determined profile VER, VER0, VER1 and the reference profile REF, REF0, REF1) whether the determined profile VER, VER0, VER1 of the selected edge 111, 112, 113 in the repair portion 121, 122, 123 is located within a predetermined tolerance range in relation to the reference profile REF, REF0, REF1.

The processing arrangement 200 is consequently configured to carry out the method explained on the basis of FIG. 6. Further, the processing arrangement 200 can be configured to carry out processing steps as explained on the basis of FIGS. 2-5.

To this end, the processing arrangement 200 additionally comprises a vacuum housing 202, the interior of which is kept at a specific vacuum, in particular with a residual gas pressure of 10⁻² mbar-10⁻⁸ mbar, by use of a vacuum pump 204. The processing arrangement can be designed as a verification and/or repair tool for lithography masks, in particular for lithography masks for EUV (“extreme ultraviolet”) or DUV (“deep ultraviolet”) lithography. In this case, the lithography mask 100 to be analyzed or to be processed is mounted on a sample stage 211 in the vacuum housing 202. The sample stage 211 of the processing arrangement 200 can be configured to set the position of the lithography mask 100 in three spatial directions and in three axes of rotation accurately to a few nanometers. The processing arrangement 200 furthermore comprises a provision unit 206 in the form of an electron column. The latter comprises an electron source 208 for providing an electron beam 210. The electron microscope 212 detects the electrons scattered back from the lithography mask 100. A further detector for secondary electrons may also be provided (not depicted here) in addition to the depicted electron microscope 212. The electron column 206 preferably has a dedicated vacuum housing 213 within the vacuum housing 202. The vacuum housing 213 is evacuated to a residual gas pressure of 10⁻⁷ mbar-10⁻⁸ mbar, for example. The electron beam 210 from the electron source 208 passes in this vacuum until it emerges from the vacuum housing 213 at the underside thereof and is then incident on the lithography mask 100.

The electron column 206 can carry out electron beam-induced processing (EBIP) processes in interaction with process gases supplied, which are supplied by a gas provision unit 214 from outside via a gas line 216 into the region of a focal point of the electron beam 210 on the lithography mask 100. This comprises in particular depositing material on the lithography mask 100 and/or etching material therefrom. In particular, the control computer 218 is configured to suitably control the electron column 206, the sample stage 211 and/or the gas provision unit 214.

Therefore, the illustrated processing arrangement 200 is configured to both analyze and check the lithography mask 100, and is at the same time also configured to process the lithography mask 100 if the check yields that processing is necessary. It should be observed that, in embodiments, the processing arrangement 200 does not necessarily unify these two functions in a single apparatus. Instead, the lithography mask 100 can be checked using a first apparatus, and the repair or processing of the lithography mask 100 can be implemented using a second apparatus.

Although the present invention has been described with reference to exemplary embodiments, it is modifiable in various ways.

### LIST OF REFERENCE SIGNS

100 Lithography mask
105 Substrate
110 Edge
110′ Regular edge
111 Selected edge
112 Selected edge
112* Repaired edge
112A Edge portion
112B Edge portion
112C Edge portion
112D Edge portion
113 Selected edge
113A Portion
113B Portion
121 Repair portion
122 Repair portion
123 Repair portion
130 Repair region
200 Processing arrangement
202 Vacuum housing
204 Vacuum pump
206 Electron column
208 Electron source
210 Electron beam
211 Sample stage
212 Electron microscope
213 Vacuum housing
214 Gas provision unit
216 Gas line
218 Determination unit/control computer
220 Processing unit
DIAG Diagram
IMG Image representation
PIX Pixel
REF Reference profile
REF0 Reference profile
REF1 Reference profile
S1 Method step
S2 Method step
S3 Method step
S4 Method step
SEL0 Selection region
SEL1 Selection region
TOL Tolerance
VER Profile
VER0 Profile
VER1 Profile
x Coordinate axis
y Coordinate axis

What is claimed is:

1. A method for checking a lithography mask for a repair of the lithography mask, the lithography mask having a plurality of edges between partial regions of the lithography mask, the object of the repair lying in an adjustment of a profile of a selected edge in a repair portion of the selected edge, the method comprising the steps of:
a) capturing an image representation of a repair region of the lithography mask comprising the repair portion of the selected edge,
b) determining the profile of the selected edge in the repair portion on the basis of the captured image representation of the repair region,
b1) determining a reference profile on the basis of a profile of an edge corresponding to the selected edge, the corresponding edge being an edge which should not be repaired or a portion of the selected edge which should not be repaired, the corresponding edge being determined on the basis of the captured image representation of the repair region, and
c) comparing the determined profile of the selected edge with the reference profile.

2. The method of claim 1, wherein step c) comprises:
virtually overlaying the reference profile on the determined profile, the reference profile being aligned at the selected edge and/or at an edge directly adjacent to the selected edge and/or at an edge connected to the selected edge at an angle which differs from 0° and/or at a corner between portions of the selected edge which extend at an angle with respect to one another which differs from 0°.

3. The method of claim 2, including:
aligning the reference profile at one or more portions of the selected edge outside of the repair portion.

4. The method of claim 1, wherein the determination of the reference profile comprises:
applying a low-pass filter and/or piecewise linear regression to smooth the reference profile.

5. The method of claim 1, wherein the determination of the reference profile comprises:
determining a plurality of respective profiles of a plurality of edges corresponding to the selected edge and
determining the reference profile as a mean of the plurality of profiles.

6. The method of claim 1, wherein the determined profile comprises a number of actual positions of the selected edge and the reference profile comprises a number of corresponding target positions, and further comprising a step d): determining whether the determined profile of the selected edge in the repair portion is located within a predetermined tolerance range in relation to the reference profile; wherein, in step d), a distance between the respective actual position and the respective target position is determined and the respective determined distance is compared with a predetermined tolerance value.

7. The method of claim 1, wherein the determined profile comprises a plurality of actual positions of the selected edge, which is a distribution of the actual positions, and wherein, following step b), at least one moment of the distribution is determined and steps b1), c) and/or a step d) are carried out on the basis of the at least one determined moment, with step d) comprising: determining whether the determined profile of the selected edge in the repair portion is located within a predetermined tolerance range in relation to the reference profile.

8. The method of claim 1, also comprising:
carrying out a repair process for the selected edge in at least one partial region of the repair portion on the basis of the comparison in accordance with step c) and/or if the profile of the selected edge in the at least one partial region is determined in a step d) to be located outside of a tolerance range, with step d) including: determining whether the determined profile of the selected edge in the repair portion is located within a predetermined tolerance range in relation to the reference profile.

9. The method of claim 8, wherein the repair process is carried out on the basis of a difference between the determined profile of the selected edge and the reference profile.

10. The method of claim 8, wherein the repair process comprises a particle beam-induced etching process and/or deposition process.

11. The method of claim 1, wherein the reference profile for the selected edge is additionally determined on the basis of a mask design for the lithography mask.

12. The method of claim 1, wherein step a) comprises:
capturing an electron microscope image of the lithography mask and/or an aerial image of the lithography mask and/or an atomic force microscope image of the lithography mask.

13. A lithography mask, in particular for EUV lithography, produced using the method of claim 1.

14. Use of a lithography mask of claim 13 in a lithography apparatus.

15. A processing arrangement for checking and/or repairing a lithography mask, the lithography mask having a plurality of edges between partial regions of the lithography mask, comprising:
a capture unit configured to capture an image representation of a repair region of the lithography mask comprising a repair portion of a selected edge,
a determination unit configured to determine a profile of the selected edge in the repair portion on the basis of the captured image representation of the repair region, and
a processing unit configured to determine a reference profile on the basis of a profile of an edge corresponding to the selected edge, the corresponding edge being an edge which should not be repaired or a portion of the selected edge which should not be repaired, the corresponding edge being determined on the basis of the captured image representation of the repair region, and the processing unit is further configured to compare the determined profile with the reference profile.

16. The processing arrangement of claim 15, wherein the processing unit is configured to virtually overlay the reference profile on the determined profile, the reference profile being aligned at the selected edge and/or at an edge directly adjacent to the selected edge and/or at an edge connected to the selected edge at an angle which differs from 0° and/or at a corner between portions of the selected edge which extend at an angle with respect to one another which differs from 0°.

17. The processing arrangement of claim 15, wherein the processing unit is configured to:
align the reference profile at one or more portions of the selected edge outside of the repair portion.

18. The processing arrangement of claim 15, wherein the processing unit is configured to:
apply a low-pass filter and/or piecewise linear regression to smooth the reference profile.

19. The processing arrangement of claim 15, wherein the processing unit is configured to:
determine a plurality of respective profiles of a plurality of edges corresponding to the selected edge and
determine the reference profile as a mean of the plurality of profiles.

20. The processing arrangement of claim 15, wherein the determined profile comprises a number of actual positions of the selected edge and the reference profile comprises a number of corresponding target positions, and
the processing unit is configured to:
determine whether the determined profile of the selected edge in the repair portion is located within a predetermined tolerance range in relation to the reference profile;
determine a distance between the respective actual position and the respective target position; and
compare the respective determined distance with a predetermined tolerance value.
